(19) United States
(12) Patent Application Publication
(10) Pub. No.: US 2008/0191684 A1
(43) Pub. Date: Aug. 14, 2008

(54) Method and configuration for measurement of harmonics in high-voltage networks

(75) Inventor: Christoph Armschat, Erlangen (DE)

Correspondence Address: LERNER GREENBERG STEMER LLP, P O BOX 2480, HOLLYWOOD, FL, 33022-2480, US

(73) Assignee: Siemens Aktiengesellschaft

(21) Appl. No.: 11/705,261

(22) Filed: Feb. 12, 2007

(51) Int. Cl. G01R 23/00

(52) U.S. Cl. 324/76.19

(57) ABSTRACT

A method measures current harmonics or voltage harmonics that occur in power supply networks. In the method, an instrument transformer produces a measurement signal for a current flowing in a conductor in a power supply network, or for a voltage that occurs on the conductor. A filter is disposed adjacent to the instrument transformer and filters out that component of the measurement signal that is associated with the current or voltage fundamental, and amplifies those components of the measurement signal that are associated with the current or voltage harmonics. The measurement signal that has been changed in this way is transmitted to an evaluation device, which is configured to determine the magnitude of the harmonics. A configuration for performing the method has such an instrument transformer and filter.

### BACKGROUND OF THE INVENTION

### Field of the Invention

The invention relates to a method for measuring current harmonics or voltage harmonics that occur in power supply networks, and to a configuration for measuring the current or voltage harmonics that occur in power supply networks, having an instrument transformer and a filter.

There is a need to measure the respectively occurring current or voltage harmonics at various points in electrical power supply networks. Information about the magnitude of the current harmonics and the voltage harmonics is required for example for open-loop or closed-loop control purposes (for example for harmonic compensation devices and harmonic filters). Information such as this is required, for example, for a method in which electrical oscillations of the same magnitude and at the same frequency but in antiphase are fed into the power supply network in response to a measurement of the magnitude of the current and/or voltage harmonics. The (undesirable) harmonics in the power supply network are greatly reduced by superimposition of the original harmonics and of the oscillations that are fed in, and as a result of mutual cancellation that occurs in this process. Knowledge of such information is frequently also desirable in order to make it possible to determine the current and/or voltage distortion which occurs at the electrical connecting point of an installation (at the so-called point of common coupling, for example to the busbar).

The magnitude of the current or voltage harmonics is normally considerably less than the magnitude of the fundamental. The magnitude (for example the amplitude) of the harmonics is often only between 0.01% and 5% of the magnitude of the fundamental. Thus, in the past, uncorrupted transmission of a measurement signal which relates to the fundamental and to the harmonics has been possible only over very short distances in the region of a few meters, and the magnitude of the harmonics was thus determined directly at the measurement point (that is to say at the location of an instrument transformer, which is installed on the conductor of the power supply network, in the “field”). This meant that the evaluation devices that are suitable for determination of the magnitude have to be installed directly at the location of the instrument transformer in the “field”, and had to be connected to the instrument transformer there. Sensitive and expensive electronic evaluation devices (for example so-called harmonic analyzers) are used for determination of the magnitude of the harmonics. Permanent installation of such a sensitive and expensive evaluation device directly adjacent too each instrument transformer, is, however, often too complex and too expensive.

### SUMMARY OF THE INVENTION

It is accordingly an object of the invention to provide a method and a configuration for measurement of harmonics in high-voltage networks that overcome the above-mentioned disadvantages of the prior art devices and methods of this general type, in which the location of the evaluation device is not restricted to the measurement point.

According to the invention, the object is achieved by a method for measuring current or voltage harmonics that occur in power supply networks, in which an instrument transformer produces a measurement signal for a current flowing in a conductor in a power supply network, or for a voltage that occurs on the conductor. A filter is disposed adjacent to the instrument transformer and filters out that component of the measurement signal that is associated with the current or voltage fundamental, and amplifies those components of the measurement signal that are associated with the current or voltage harmonics. The measurement signal that has been changed in this way is transmitted to an evaluation device, which is configured to determine the magnitude of the harmonics. The measurement signal produced by the instrument transformer is in this case proportional to the (primary) current flowing in the conductor of the power supply network, or to the (primary) voltage that occurs on the conductor. In this method, it is particularly advantageous that the changed (filtered) measurement signal can be transmitted over relatively long distances to the evaluation device without the measurement result being made significantly worse by the attenuation that occurs during the transmission of the measurement signal or radiated interference injected during the transmission of the measurement signal. This is achieved by using the filter that it disposed adjacent to the instrument transformer to filter out that component of the measurement signal (that is to say the magnitude of the component of the measurement signal is greatly reduced) which is associated with the current or voltage fundamental, and by amplifying those components of the measurement signal which are associated with the current of voltage harmonics. The amplification of the components that are associated with the harmonics results in that neither the attenuation during the transmission of the changed measurement signal nor any radiated interference that may occur leads to any significant deterioration in the signal quality of the changed measurement signal. The method can also advantageously be used in particular in electrical high-voltage networks with high voltage conductors.

The method can be carried out in such a way that the filter is connected to the instrument transformer to form a unit. This advantageously results in that the filter is disposed physically close to the instrument transformer, and thus also to the measurement point on the conductor, thus resulting in a short transmission path for the measurement signal from the conductor to the filter. A short transmission path such as this makes it possible to avoid unacceptably high attenuation and susceptibility to radiated interference comparatively easily and at low cost.

The method can be carried out in such a way that the filter is disposed in a connecting terminal box of the instrument transformer. This configuration advantageously allows the filter to be installed in a manner that protects it against mechanical loads and against environmental influences.

The method can be carried out in such a manner that the transfer function of the filter has a high-pass filter characteristic. This advantageously makes it possible to use a high-pass filter that is known per se, for example a Tchebyscheff filter.

The method can also be carried out in such a way that a current transformer whose core is composed of a material with low hysteresis is used as the instrument transformer. A material such as this with low hysteresis has a low magnetization current draw. One example of a material such as this is nickel iron. In the case of a material such as this with low hysteresis, the current or voltage harmonics are advantageously mapped, true to the original, in the measurement signal of the instrument transformer. This is also in particular advantageously true when the fundamental has a large amplitude and the harmonics have small amplitudes.

The method can also be carried out in such a way that an instrument transformer with a uniform-field coil is used. In this case, a good signal quality of the measurement signal can advantageously be achieved at high frequencies, without any magnetization current being drawn.

The method can also be carried out in such a way that a voltage transformer that has a capacitive voltage divider is used as the instrument transformer. The use of a capacitive voltage divider advantageously makes it possible to also use the method for the measurement of small-amplitude harmonics superimposed on large-amplitude voltage fundamentals.

The method can also be carried out in such a way that a voltage transformer whose measurement signal has a root mean square value of between 50 and 230 V is used as the instrument transformer. A measurement signal with a root mean square value of the between 50 and 230 V, for example a measurement signal with a root mean square value of 100 V, has the advantage that the influence of possible radiated interference (which normally leads to interference signals with very small voltage amplitudes) is reduced, since these interference signals with small voltage amplitudes make up, in percentage terms, only a very small proportion of the measurement signal with the root mean square value of between 50 of 230 V.

The method can also be carried out in such a way that electrical lines that transmit the measurement signal to the filter are electromagnetically shielded by a metal tube that surrounds these lines. The electromagnetic shielding of the electrical lines that transmit the measurement signal to the filter, by a (solid) metal tube (which surrounds the lines) allows highly effective shielding of the lines. This is particularly advantageous in comparison to the use of lines that are shielded by a flexible metal mesh, using which it is not possible to achieve such high-quality shielding.

The method can also be carried out in such a manner that the changed measurement signal is transmitted to the evaluation device via a transmission path whose length is several times greater than the distance between the conductor and filter. This advantageously makes it possible to arrange the evaluation device at a long distance from the instrument transformer as well, for example in the building where the closest control room is located. One evaluation device such as this can then be used for a plurality of instrument transformers, thus resulting in a cost-effective solution. For example, the length of the transmission path may be greater by a factor of 100 than the shortest physical distance between the conductor and filter. If, by way of example, the distance between the conductor and filter is assumed to be 5 m, this thus results in possible transmission path lengths of up to about 500 m.

The object mentioned initially is likewise achieved according to the invention by a configuration having an instrument transformer for a power supply network and a filter, in which the instrument transformer is configured to produce a measurement signal for a current flowing in a conductor in a power supply network, or for a voltage which occurs on the conductor and in which the filter is configured to filter out that component of the measurement signal which is associated with the current or voltage fundamental, and to amplify those components of the measurement signal which are associated with the current or voltage harmonics. The configuration has the particular advantage that the measurement signal which is changed by the filter can be transmitted over relatively long distances to an evaluation device (which is configured to determine the magnitude of the harmonics) without the measurement result being made significantly worse by attenuation occurring during the transmission of the measurement signal or by interference radiation injected during the transmission of the measurement signal. This is achieved by the filter that is disposed adjacent to the instrument transformer filtering out that component of the measurement signal (that is to say the magnitude of this component of the measurement signal is greatly reduced) which is associated with the current or voltage fundamental, and by amplifying those components of the measurement signal which are associated with the current or voltage harmonics. Amplification of the components that are associated with the harmonics results in that neither the attenuation during the transmission of the changed measurement signal nor any radiated interference that may occur leads to any significant deterioration in the signal quality of the changed measurement signal. In particular, the configuration can advantageously also be used in electrical high-voltage networks with high-voltage conductors.

In this configuration, the filter can be connected to the instrument transformer to form a unit.

In particular, the filter can be disposed in a connecting terminal box for the instrument transformer.

Furthermore, the transfer function of the filter in the configuration may have a high-pass filter characteristic.

The configuration can be configured such that the instrument transformer is a current transformer whose core is composed of a material with low hysteresis. A material such as this with low hysteresis has a low magnetization current draw.

The instrument transformer in the configuration may advantageously have a uniform-field coil.

The configuration can also be designed such that the instrument transformer is a voltage transformer that has a capacitive voltage divider.

The configuration can be configured such that the instrument transformer is a voltage transformer whose measurement signal has a root mean square value of between 50 and 230 V.

The configuration can also advantageously be configured such that it has a metal tube that surrounds electrical lines that transmit the measurement signal to the filter. The metal tube is used for electromagnetic shielding of these lines.

Furthermore, the configuration may advantageously have a transmission device for transmission of the measurement signal that is changed by the filter to an evaluation device, which is configured to determine the magnitude of the harmonics.

In this case, the transmission device may be configured to transmit the measurement signal, which has been changed by the filter, via a transmission path whose length is several times greater than the distance between the conductor and the filter.

Other features that are considered as characteristic for the invention are set forth in the appended claims.

Although the invention is illustrated and described herein as embodied in a method and a configuration for measurement of harmonics in high-voltage networks it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIG. 1 is a diagrammatic, perspective and partially cutaway view of an exemplary embodiment of an instrument transformer according to the prior art;

FIG. 2 is a block circuit diagram of a first exemplary embodiment of a configuration and of a method for measurement of current harmonics according to the invention;

FIG. 3 is a block circuit diagram of a second exemplary embodiment of the configuration and the method for measurement of voltage harmonics according to the invention; and

FIG. 4 is a graph showing an exemplary embodiment of a transfer function of a filter according to the invention.

### DESCRIPTION OF THE PREFERRED EMBODIMENTS

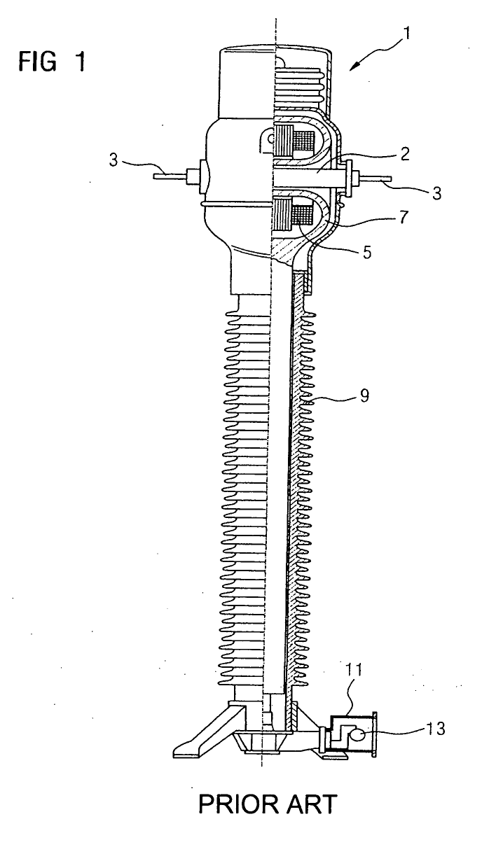

Referring now to the figures of the drawings in detail and first, particularly to FIG. 1 thereof, there is shown an instrument transformer 1 for currents (current transformer). The instrument transformer 1 has a primary conductor 2 with connections 3. One conductor of a power supply network for which the harmonics of the current flowing through the conductor are intended to be measured is connected by the connections 3 to the primary conductor 2 in such a manner that the entire conductor current flows through the primary conductor 2. A winding 5 that is wound around an iron core of the current transformer is isolated from the primary conductor 2 by high-voltage insulation 7. The entity formed by an iron core on the winding is referred to in the following text as a core 5.

A measurement signal produced from the core 5 is transmitted by lines that are disposed in the interior of a porcelain insulator 9 to a connection terminal box 11, in which connecting terminals 13 are located. By way of example, the connecting terminals 13 can be connected to an evaluation device for evaluation of the current measurement signal produced from the core 5. When used in high-voltage power supply networks, the length of the porcelain insulator 9 may be several meters, for example 3 to 5 m.

Together with the primary conductor 2, the core 5 forms a magnetic transformer which, as a result of the (high) current flowing through the primary conductor, produces a (smaller) current flowing through the core 5, which can be processed further by the evaluation device. A uniform-field coil can also be used instead of the core 5.

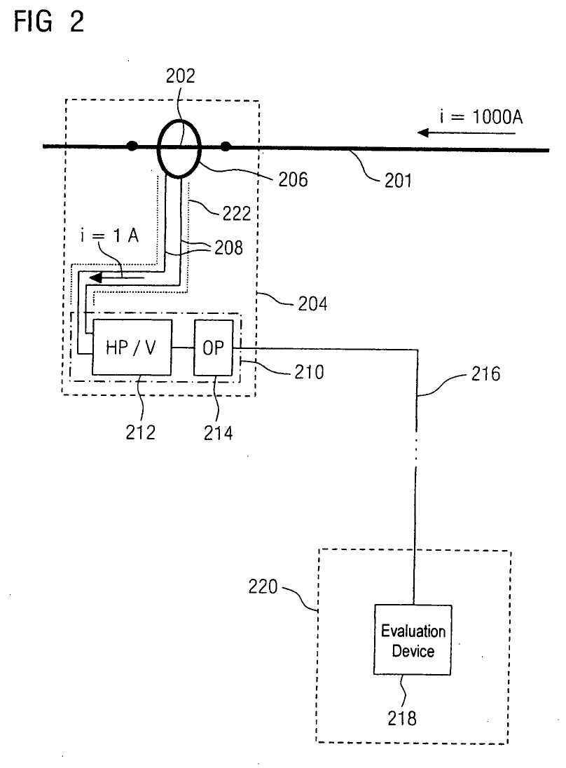

FIG. 2 shows one exemplary embodiment of a method for measurement of current harmonics and a corresponding configuration. A current i flows through a conductor 201 in a power supply network, which is not illustrated in any more detail. In the exemplary embodiment, the current i has a root mean square current level of 1,000 A, and is composed of a fundamental and harmonics. The fundamental is at a frequency of 50 Hz, and the harmonics are at frequencies of n×50 Hz (n=2, 3, 4, 5, 6 etc). The current i flows through a primary conductor 202 of a current instrument transformer 204. The current instrument transformer 204 also has a core 206, which is connected via signal lines 208 to a connecting terminal box 210 of the current instrument transformer 204. The core 206 produces a measurement signal in the form of a current that is proportional to the current flowing through the primary conductor 202, but has a much smaller magnitude (for example a current with a root mean square magnitude of 1 A).

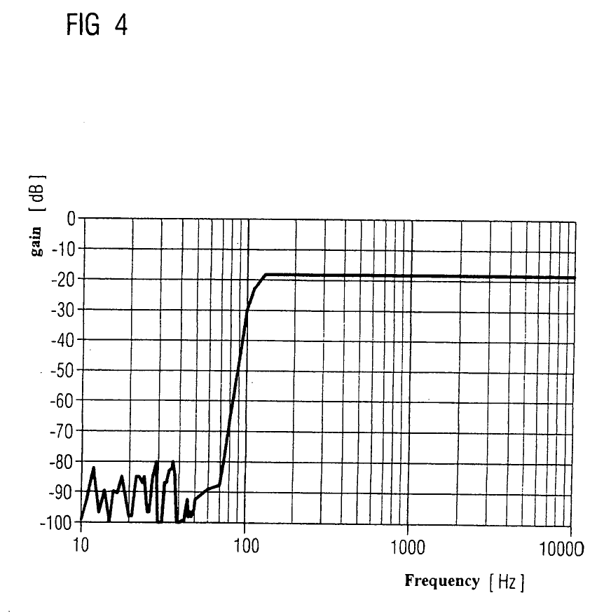

The measurement signal is transmitted via signal lines 208 to a filter 212 (HP=high-pass filter, V=amplifier). The filter 212, which is disposed adjacent to the instrument transformer 204, filters that portion of the current measurement signal which is associated with the current fundamental (frequency 50 Hz), and amplifies those components of the measurement signal which are associated with harmonics of the current (frequencies 100 Hz, 150 Hz, etc.). The filter has a transfer function with a high-pass filter characteristic, for example the transfer function illustrated in FIG. 4. The filter 212 therefore changes the measurement signal, by carrying out high-pass filtering. The measurement signal which has been changed (filtered) in this way is transmitted via a transmission device 214 and a transmission path 216 to an evaluation device 218 which, in the exemplary embodiment, is disposed in a control room 220 for the power supply network.

The filter 212 in the exemplary embodiment is provided by an electronic circuit composed of electronic components (inter alia electronic circuits with external circuitry). The electronic circuit is supplied with auxiliary power by a voltage supply device that is not illustrated in FIG. 2, and is a so-called active electronic filter. An encapsulated configuration of the filter ensures, inter alia, that this filter can operate at outside temperatures (no need for the complexity of air-conditioning), and that any moisture that may occur also causes no damage to the filter. A filter such as this is occasionally also referred to as an “outdoor filter”. The filter can also be disposed outside the instrument transformer 204, and may be connected to it via the signal lines. The configuration in the connecting terminal box 210 of the instrument transformer 204 should be regarded only as an example.

In the exemplary embodiment, an optical transmitter (OP) is used as the transmission device 214 and feeds the changed measurement signal into a transmission path 216 in the form of optical waveguides. However, this represents only one possible embodiment, and, by way of example, the electrical output signal from the filter 212 in other embodiments may also be transmitted directly (without any additional transmission device) in the form of an electrical analog signal by a transmission path in the form of electrical lines to the evaluation device 218.

The evaluation device 218 is configured to determine the magnitude of the harmonics, that is to say the evaluation device is able to determine the magnitude of the individual harmonics (for example in volts). By way of example, such determination of the magnitude of the individual harmonics can be carried out by a Fourier transformation. Evaluation devices such as these are known per se and are also referred to as “harmonic analyzers”.

In the exemplary embodiment, the filter 212 is connected to the current instrument transformer 204 to form a unit, in detail, in the exemplary embodiment, the filter 212 (as well as the transmission device 214) is disposed in the connecting terminal box 210 of the current instrument transformer 204. The filter 212 and the transmission device 214 are thus protected against damaging environmental influences, such as wind or moisture. The electrical lines 208 (signal lines) which transmit the measurement signal from the core 206 to the filter 212 are located in the interior of a metal tube 222, which very effectively electromagnetically shields these lines. This rigid solid metal tube 222 advantageously makes it possible to achieve better electromagnetic shielding at the signal lines 208 than will be possible, for example, by conventional flexible signal lines with metal mesh sheathing.

The current instrument transformer 204 (which represents a magnetic transformer) has an iron core that is composed of a material with low hysteresis. The expression a material with low hysteresis is understood as meaning a material whose hysteresis curve has a small area. The hysteresis curve is a graphical representation of the magnetic flux density B plotted against the magnetic field strength H. In other words, a material with low hysteresis has a low magnetic resonance flux density Br. The use of an iron core composed of a material with low hysteresis has the advantageous effect that the harmonics are mapped true to the original in the measurement signal that is produced from the core 206, in particular even when the current amplitude is small. One core material with low hysteresis is, for example, nickel iron.

The filter 212 virtually completely filters out the component of the measurement signal that originates from the fundamental of the current I. Furthermore, those components of the measurement signal that originate from the harmonics are amplified. The (filtered) measurement signal that is changed by the filter can thus advantageously also be transmitted via the transmission device 214 and the transmission path 216 to the evaluation device 218 when the transmission path 216 has a considerable length. In the exemplary embodiment, the length of the transmission path 216 is several times greater than the shortest physical distance between the conductor 201 and the filter 212. This distance between the conductor 201 and the filter 212 corresponds approximately to the length of the signal lines 208. In the exemplary embodiment, the length of the signal line is 3 m, while the length of the transmission path is 300 m.

The amplification of those components of the measurement signal which are associated with the harmonics ensures that, despite the attenuation of the measurement signal which takes place in the transmission path 216 and despite the radiated interference of small-amplitude interference signals which may take place on this transmission path 216, a measurement signal arrives at the evaluation device 218, whose signal quality if adequate for the subsequent determination of the magnitude of the harmonics and, if required, for further analyses. The filtering out (elimination) of the fundamental and the amplification of the harmonics in the measurement signal make it possible to achieve an accuracy in the determination of the magnitude of the harmonics in the region of 0.01% to 0.001%.

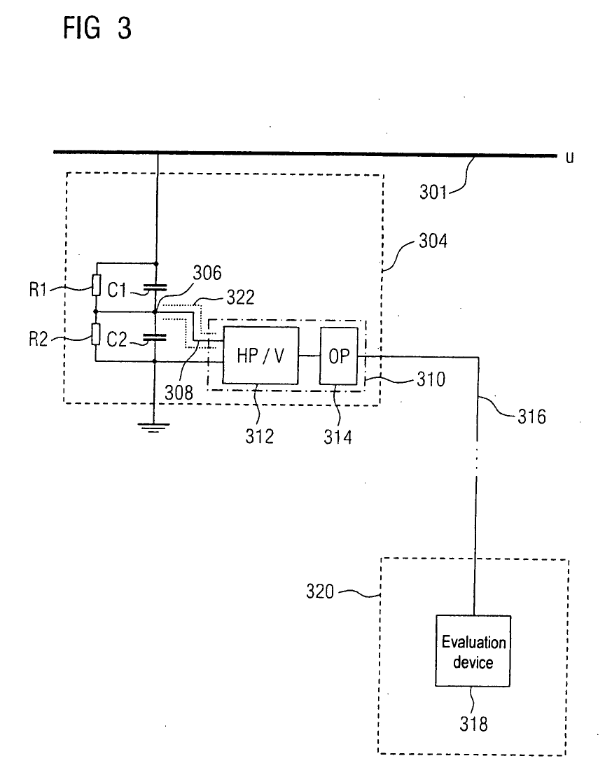

By way of example, FIG. 3 shows a method and a configuration for measurement of voltage harmonics which occur in power supply networks. A voltage u occurs on a conductor 301 in a power supply network. In the exemplary embodiment, the root mean square magnitude of the voltage u is 362 kV, which is composed of a fundamental and harmonics. The fundamental is, for example at a frequency of 50 Hz, while the harmonics are at frequencies of n×50 Hz (n=2, 3, 4, 5, 6 etc.). In other exemplary embodiments, the fundamental may also be at a frequency of 60 Hz, with the harmonics being at frequencies of n×60 Hz (n=2, 3, 4, 5, 6 etc.).

The conductor 301 is connected to a voltage instrument transformer 304. The voltage instrument transformer 304 has a capacitive voltage divider that, in the exemplary embodiment, includes a first resistance R1 (primary high-voltage resistance), a second resistance R2 (secondary resistance), a first capacitor C1 and a second capacitor C2. The voltage divider reduces the voltage on the conductor 301 (the voltage of the high-voltage network) in the ratio 362,000 V:root (3)) to 100 V, corresponding to (209,000 V//100 V). The measurement signal is tapped off at the point 306 in the voltage divider in the form of a measurement voltage, and is transmitted via a signal line 308 to a filter 312, which is installed in a connecting terminal box 310 for the instrument transformer 304. The measurement signal is also referred to as a “secondary tap”. The signal line 308 is electromagnetically shielded from radiated interference by a metal tube 322.

The measurement signal that occurs at the point 306 on the capacitive voltage divider is in the form of a measurement voltage that has a root mean square value of between 50 and 230 V. By way of example, this measurement voltage may have a root mean square value of 100 V. A measurement voltage with a root mean square value which is chosen to be as high as this and is unusually high for electronic filters has the advantage that the influence of possible radiated interference is reduced: this is because radiated interference such as this normally leads to relatively low amplitude interference voltages (for example in the millivolt range). The influence of small amplitude interference voltages such as these is less when the measurement signal has a comparatively high root mean square value of between, for example, 50 and 230 V.

The filter 312 filters out of the measurement signal that component which is associated with the fundamental of the voltage, and amplifies those components that are associated with the harmonics of the voltage. The rest of the construction corresponds to the construction which has already been explained in conjunction with FIG. 2: the measurement signal which has been changed (filtered) in this way is transmitted by a transmission device 314 via a transmission path 316 to an evaluation device 318, which is disposed in a control room 320. The evaluation device 318 determines the magnitudes of the voltage harmonics, and further analyses of the harmonics are carried out, if required.

By way of example, FIG. 4 shows a transfer function for the filter 312 in the form of a graph. The graph shows a gain in decibels (dB) and plotted against the frequency in Hertz (Hz) on a logarithmic/linear scale.

As can clearly be seen the filter has very high attenuation (approximately −92 dB), at a frequency of 50 Hz (frequency of the voltage fundamental), while the filter has considerably less attenuation in the frequency ranges of the harmonics (that is to say at 100 Hz, 150 Hz, 200 Hz) (approximately −30 dB, at a frequency of 100 Hz, approximately −18 dB at a frequency of 150 Hz, while the attenuation remains constant at about −18 dB at frequencies above 150 Hz). This transfer function has a pronounced high-pass filter characteristic. The filter is in the form of an active high-pass filter. The filter gain can be varied as required in order to match the signal level of the changed measurement signal to the amplitude bandwidth of the transmission path. The illustrated characteristic is shifted in the vertical direction, as the gain is changed.

The component of the measurement signal at a frequency of 50 Hz is very highly attenuated (filtered out), with this being the component associated with the fundamental. After a transitional area, those components of the measurement signal which are associated with the harmonics of the voltage, that is to say from about 150 Hz, are optimally matched to the amplitude bandwidth of the transmission path. In the exemplary embodiment, this is achieved by negative amplification, but in other exemplary embodiments can also be carried out by positive amplification. These components are amplified by the filter such that they utilize the predetermined amplitude bandwidth of the transmission path 316 (that is to say they occupy it as completely as possible). In the exemplary embodiment, the transmission path 316 has an amplitude bandwidth of +/−10 V (0 to +/−10 V. In this case, the instrument transformer is also at the same time decoupled from the transmission path. The measurement signal, which is weak in the harmonic range, from the instrument transformer is amplified by the filter to the power level required for transmission (power gain). The filter 212 has a similar transfer function.

A method and a configuration have been described by which current and voltage harmonics that occur in power supply networks can be measured. The configuration of a filter adjacent to the instrument transformer, with the filter filtering out those components of the measurement signal which are associated with the current or voltage fundamental and amplifying those components of the measurement signal which are associated with the current or voltage harmonics means that the measurement signal which has been changed by the filter could be transmitted over transmission paths of considerable length to evaluation devices without the measurement result being made significantly worse by the attenuation of radiated interference which occurs during the transmission via the transmission path.

I claim:

1. A method for measuring one of current harmonics and voltage harmonics occurring in power supply networks, which comprises the steps of:
providing an instrument transformer producing a measurement signal for one of a current flowing in a conductor in a power supply network and a voltage occurring on the conductor;
disposing a filter adjacent to the instrument transformer for filtering out that component of the measurement signal associated with a current fundamental or a voltage fundamental, and amplifies other components of the measurement signal associated with current harmonics or voltage harmonics resulting in a filtered measurement signal; and
transmitting the filtered measurement signal to an evaluation device for determining a magnitude of the harmonics.

2. The method according to claim 1, which further comprises connecting the filter to the instrument transformer to form a unit.

3. The method according to claim 1, which further comprises disposing the filter in a connecting terminal box of the instrument transformer.

4. The method according to claim 1, which further comprises providing the filter with a transfer function having a high-pass filter characteristic.

5. The method according to claim 1, which further comprises providing the instrument transformer as a current transformer having a core composed of a material with low hysteresis.

6. The method according to claim 1, which further comprises providing the instrument transformer with a uniform-field coil.

7. The method according to claim 1, which further comprises providing a voltage transformer having a capacitive voltage divider as the instrument transformer.

8. The method according to claim 1, which further comprises providing a voltage transformer outputting the measurement signal with a root mean square value of between 50 and 230 V as the instrument transformer.

9. The method according to claim 1, which further comprises:
providing electrical lines for transmitting the measurement signal to the filter; and
electromagnetically shielding the electrical lines with a metal tube surrounding the electrical lines.

10. The method according to claim 1, which further comprises transmitting the filtered measurement signal to the evaluation device via a transmission path having a length being several times greater than a distance between the conductor and the filter.

11. A configuration for a power supply network, the configuration comprising:
an instrument transformer producing a measurement signal for one of a current flowing in a conductor in a power supply network and a voltage occurring on the conductor; and
a filter connected to said instrument transformer, said filter filtering out that component of the measurement signal associated with a current fundamental or a voltage fundamental, and amplifying other components of the measurement signal associated with current harmonics or voltage harmonics.

12. The configuration according to claim 11, wherein said filter is connected to said instrument transformer to form a unit.

13. The configuration according to claim 11, wherein:
said instrument transformer has a connecting terminal box; and
said filter is disposed in said connecting terminal box.

14. The configuration according to claim 11, wherein said filter has a transfer function with a high-pass filter characteristic.

15. The configuration according to claim 11, wherein said instrument transformer is a current transformer with a core composed of a material with low hysteresis.

16. The configuration according to claim 11, wherein said instrument transformer has a uniform-field coil.

17. The configuration according to claim 11, wherein said instrument transformer is a voltage transformer having a capacitive voltage divider.

18. The configuration according to claim 11, wherein said instrument transformer is a voltage transformer outputting the measurement signal with a root mean square value of between 50 and 230 V.

19. The configuration according to claim 11, wherein said instrument transformer has electrical lines transmitting the measurement signal to said filter and a metal tube surrounding said electrical lines.

20. The configuration according to claim 11, further comprising:
an evaluation device for determining a magnitude of the harmonics; and
a transmission device for transmitting the filtered measurement signal to said evaluation device to determine the magnitude of the harmonics, said transmission device connected to said filter.

21. The configuration according to claim 20, wherein said the transmission device transmits the filtered measurement signal, via a transmission path having a length being several times greater than a distance between said conductor and said filter.
